(19) United States
(12) Patent Application Publication
(10) Pub. No.: US 2026/0229260 A1
(43) Pub. Date: Aug. 6, 2026

(54) COMPUTING DEVICE, DATA TRANSFER METHOD, AND COMPILER DEVICE

(71) Applicant: Preferred Networks, Inc., Tokyo (JP)

(72) Inventors: Kodai UEYOSHI, Tokyo (JP); Yutetsu TAKATSUKASA, Tokyo (JP)

(21) Appl. No.: 19/459,486

(22) Filed: Jan. 26, 2026

(30) Foreign Application Priority Data
Jan. 31, 2025 (JP) 2025-014675

(51) Int. Cl. G11C 7/10

(52) U.S. Cl. CPC G11C 7/1006; G11C 7/1096

(57) ABSTRACT

A transfer circuit includes a transfer circuit; and two or more memories connected to the transfer circuit. The transfer circuit is configured to acquire data from a transmission source; acquire first control information for determining a write position of the data, from the transmission source; acquire second control information for determining the write position of the data, the second control information being different from the first control information; determine the write position of the data based on the first control information and the second control information; transmit the data to one or more memories included in the two or more memories based on the determination. The second control information includes at least information for specifying the one or more memories to which the data is to be transmitted.

### CROSS-REFERENCE TO RELATED APPLICATIONS

This patent application is based on and claims priority to Japanese Patent Application No. 2025-014675 filed on Jan. 31, 2025, the entire contents of which are incorporated herein by reference.

### TECHNICAL FIELD

The present disclosure relates to a computing device, a data transfer method, and a compiler device.

### BACKGROUND

For example, a semiconductor memory having a large storage capacity and bandwidth, such as High Band Memory (HBM) standardized by the Joint Electron Device Engineering Council (JEDEC), is used.

### RELATED ART DOCUMENT

### Patent Document

[Patent Document 1] Japanese Laid-open Patent Application Publication No. 2019-67469

### SUMMARY

According to one aspect of the present disclosure, a transfer circuit includes a transfer circuit; and two or more memories connected to the transfer circuit. The transfer circuit is configured to acquire data from a transmission source; acquire first control information for determining a write position of the data, from the transmission source; acquire second control information for determining the write position of the data, the second control information being different from the first control information; determine the write position of the data based on the first control information and the second control information; transmit the data to one or more memories included in the two or more memories based on the determination. The second control information includes at least information for specifying the one or more memories to which the data is to be transmitted.

### BRIEF DESCRIPTION OF THE DRAWINGS

FIG. 1 is a block diagram illustrating an example of a computing device;

FIG. 2 is a block diagram illustrating an example of a memory interface;

FIG. 3 is a diagram for explaining a first example of a data transfer process according to a first embodiment;

FIG. 4 is a diagram for explaining a second example of the data transfer process according to the first embodiment;

FIG. 5 is a diagram for explaining a third example of the data transfer process according to the first embodiment;

FIG. 6 is a diagram for explaining a fourth example of the data transfer process according to the first embodiment;

FIG. 7 is a flowchart illustrating an example of a writing process according to the first embodiment;

FIG. 8 is a flowchart illustrating an example of a reading process according to the first embodiment;

FIG. 9 is a diagram for explaining an example of a data transfer process according to a second embodiment;

FIG. 10 is a diagram for explaining a first example of a reallocation process;

FIG. 11 is a diagram for explaining a second example of the reallocation process;

FIG. 12 is a flowchart illustrating an example of a writing process according to the second embodiment;

FIG. 13 is a flowchart illustrating an example of a reading process according to the second embodiment; and

FIG. 14 is a block diagram illustrating an example of a hardware configuration of a computer.

### DETAILED DESCRIPTION

Hereinafter, embodiments of the present disclosure will be described with reference to the accompanying drawings. Here, in the present specification and the accompanying drawings, components having substantially the same functional configuration are denoted by the same reference numerals and duplicated descriptions will be omitted.

### First Embodiment

A first embodiment of the present disclosure is an example of a computing device configured to perform a predetermined operation. The computing device may include any computing unit configured to execute any operation. The computing device may, for example, function as an accelerator configured to perform an operation related to a machine learning model. The operation related to the machine learning model may include an operation to perform a training process and may include an operation to perform an inference process, for example. The machine learning model may include, for example, a neural network, a generative model, a foundation model, a Large Language Model (LLM), a Space State Model (SSM), and the like. The computing device may be connected to another processor. The other processor may include a central processing unit (CPU) or a graphics processing unit (GPU). The computing device may function as a computer configured to perform any computation.

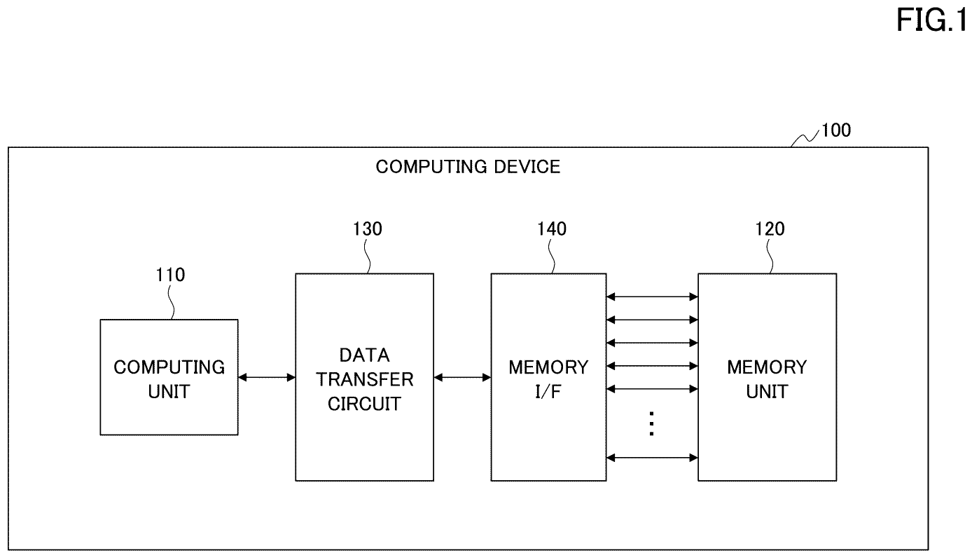

The computing device according to the present embodiment will be described with reference to FIG. 1. FIG. 1 is a block diagram illustrating an example of the computing device.

As illustrated in FIG. 1, a computing device 100 may include a computing unit 110, a memory unit 120, a data transfer circuit 130, and a memory interface (I/F) 140. FIG. 1 illustrates, for example, the computing device 100 including one combination of the computing unit 110, the memory unit 120, the data transfer circuit 130, and the memory interface 140, but the number of combinations may be suitably selected. That is, the computing device 100 may include two or more combinations of the computing unit 110, the memory unit 120, the data transfer circuit 130, and the memory interface 140. Additionally, when the computing device 100 includes two or more combinations of the computing unit 110, the memory unit 120, the data transfer circuit 130, and the memory interface 140, the data transfer circuits 130 may be connected to each other to perform data communication.

Here, the computing unit 110, the data transfer circuit 130, and the memory interface 140 may be implemented by one or more processing circuits (processors). The computing unit 110 may include one or more processing circuits. The data transfer circuit 130 may include one or more processing circuits. The memory interface 140 may include one or more processing circuits. That is, the computing device 100 may include one or more processors.

At least two of the computing unit 110, the data transfer circuit 130, and the memory interface 140 may be integrated into one processing circuit. For example, the computing unit 110 and the memory interface 140 may be integrated into one processing circuit. As another example, the data transfer circuit 130 and the memory interface 140 may be integrated into one processing circuit. Additionally, the computing device 100 may include another processing circuit. For example, the other processing circuit may be connected between the computing unit 110 and the memory interface 140.

The computing unit 110 is an example of a processing circuit configured to perform a predetermined operation. The predetermined operation may include an operation related to a machine learning model. The computing unit 110 may perform a predetermined operation based on electronic data stored in the memory unit 120. The computing unit 110 may perform control for storing electronic data including operation results in the memory unit 120. Hereinafter, the electronic data may be simply referred to as “data”.

The computing unit 110 is an example of a computing circuit. The computing device 100 may include one or more other computing circuits different from the computing unit 110. The other computing circuits may be connected to the same data transfer circuit 130 as the computing unit 110.

For example, the computing unit 110 may perform a predetermined operation according to an instruction issued by a CPU of a host connected to the computing device 100. The instruction issued by the CPU of the host may be included in a control program generated by a compiler device. The instruction issued by the CPU of the host may be a single instruction, multiple data (SIMD) instruction. The SIMD instruction is an instruction set for processing a plurality of data in parallel by one instruction.

The memory unit 120 is an example of a storage device configured to store data. The memory unit 120 may store data used for the operation by the computing unit 110. The memory unit 120 may store data including operation results by the computing unit 110.

The memory unit 120 may store, for example, data related to the machine learning model. The data related to the machine learning model may include, for example, parameters of the machine learning model. The parameters of the machine learning model may include, for example, parameters of a neural network, a transformer, or a state-space model. The data related to the machine learning model may include, as another example, intermediate data of the machine learning model. The intermediate data of the machine learning model may include, for example, a key value cache of the transformer or state information of the state-space model.

The memory unit 120 may include, for example, a dynamic random access memory (DRAM), a static random access memory (SRAM), a magnetoresistive random access memory (MRAM), a phase-change RAM (PRAM), a flash memory, and the like. The memory unit 120 may include one or more DRAMs, one or more SRAMs, one or more MRAMs, one or more PRAMs, one or more flash memories, and the like. That is, the memory unit 120 may include a plurality of physically different memories. The memory unit 120 may, for example, be a semiconductor memory having a 3-dimensional stacked structure. The memory unit 120 may be, for example, a semiconductor memory conforming to the HBM standard (e.g., HBM3E).

The memory unit 120 may include a plurality of channels. The plurality of channels may include physical channels and pseudo channels. The pseudo channels may correspond to one or more physical channels. For example, the memory unit 120 may include two pseudo channels for one physical channel. For example, the memory unit 120 may include 16 physical channels and 32 pseudo channels. The number of channels of the memory unit 120 is an example, and any number of channels may be included.

Each of the channels of the memory unit 120 may independently transfer data. Therefore, the computing device 100 can use each of the channels of the memory unit 120 as one memory. It may be said that the computing device 100 includes a number of memories equal to the product of the number of memory units 120 and the number of channels of the memory unit 120. That is, the computing device 100 may include at least 2 memories.

Additionally, the memory unit 120 may include a plurality of memory banks. Each of the memory banks of the memory unit 120 may independently transfer data. Therefore, the computing device 100 can use each of the memory banks of the memory unit 120 as one memory. It may be said that the computing device 100 includes a number of memories equal to the product of the number of memory units 120 and the number of memory banks of the memory unit 120.

The data transfer circuit 130 is an example of a processing circuit configured to control data transfer in the computing device 100. The data transfer circuit 130 may control data transfer between the computing unit 110 and the memory unit 120. The data transfer circuit 130 may control data transfer with another data transfer circuit 130. The data transfer circuit 130 may control data transfer between an external device such as a host and the memory unit 120. The data transfer circuit 130 may be, for example, a direct memory access (DMA) controller.

The memory interface 140 is an example of a processing circuit that connects the memory unit 120 to the data transfer circuit 130. The memory interface 140 is an example of a transfer circuit. When the memory interface 140 is integrated with another processing circuit (e.g., the data transfer circuit 130, the computing unit 110, or the like), the processing circuit is another example of the transfer circuit. In other words, a processing circuit having a function of the memory interface 140 may be included in the transfer circuit.

The memory interface 140 may transfer data from the data transfer circuit 130 to the memory unit 120 according to a data transfer instruction (a write instruction) from the data transfer circuit 130. The memory interface 140 may transfer data from the memory unit 120 to the data transfer circuit 130 according to a data transfer instruction (a read instruction) from the data transfer circuit 130. The data transfer between the data transfer circuit 130 and the memory interface 140 may be performed in parallel. The memory interface 140 may be, for example, a DMA controller.

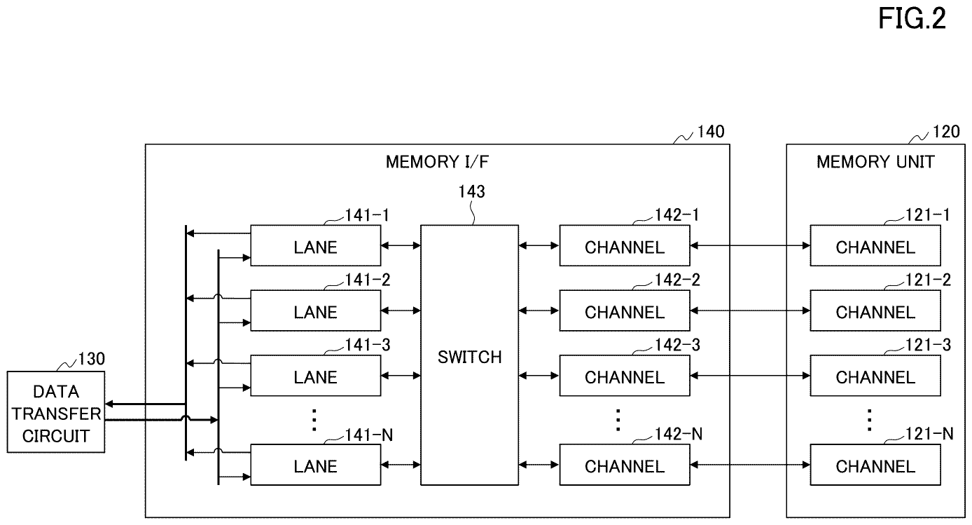

A configuration of the memory interface 140 will be described in more detail with reference to FIG. 2. FIG. 2 is a block diagram illustrating an example of the memory interface.

As illustrated in FIG. 2, the memory interface 140 may include one or more lanes 141 (141-1 to 141-N), one or more channels 142 (142-1 to 142-N), and a switch 143. The memory unit 120 connected to the memory interface 140 may include one or more channels 121 (121-1 to 121-N). Here, N is the number of channels of the memory unit 120. N may be, for example, 32.

The channel 142 and the channel 121 may be connected in any form in which data transfer can be performed. The channel 142 and the channel 121 may be connected by a physical bus. The channel 142 and the channel 121 may be connected by a logical bus.

The memory interface 140 receives a data transfer instruction from the data transfer circuit 130. The data transfer instruction may be a write instruction or a read instruction. The write instruction is an instruction for storing, in the memory unit 120, data transferred from the data transfer circuit 130. The read instruction is an instruction for reading data stored in the memory unit 120 and transferring the data to the data transfer circuit 130.

The data transfer instruction may be generated by a compiler device. The data transfer instruction may be issued by a CPU of a host connected to the computing device 100. The data transfer instruction may be issued by a control program executed by the CPU of the host.

Data input from the data transfer circuit 130 to the memory interface 140 is divided into N pieces and input to N lanes 141-1 to 141-N. The data input to the memory interface 140 may be previously divided into N pieces. The data output from the N lanes 141-1 to 141-N is combined into one piece of data and output to the data transfer circuit 130. The combining method of the data output from the N lanes 141-1 to 141-N may be controlled based on the bandwidth of the data transfer circuit 130. The data input from the data transfer circuit 130 to the memory interface 140 and the data output from the memory interface 140 to the data transfer circuit 130 may be transferred in the same data format.

For example, the data input to the memory interface 140 may be divided based on the bandwidth of the channel 121 of the memory unit 120. For example, the data input to the memory interface 140 may be divided based on the number of channels of the memory unit 120. For example, when the memory unit 120 includes 32 channels 121 (i.e., N=32) and 8192-bit data is input to the memory interface 140, 256-bit data may be input to each of the lanes 141-1 to 141-N.

The lane 141 is a circuit configured to transfer data to and from the data transfer circuit 130. The lane 141 may transfer the data input from the data transfer circuit 130 to any of the channels 142-1 to 142-N. The lane 141 may transfer the data output from one of the channels 142-1 to 142-N to the data transfer circuit 130. The N lanes 141-1 to 141-N of the memory interface 140 may share an address and a burst length.

The channel 142 is a circuit configured to transfer data to and from the memory unit 120. The channel 142-n transfers the data transferred from one of the lanes 141-1 to 141-N to the channel 121-n of the memory unit 120. The channel 142-n transfers the data output from the channel 121-n of the memory unit 120 to one of the lanes 141-1 to 141-N. Here, n is an integer from 1 to N.

The switch 143 is a circuit configured to output the input from the lane 141 to the channel 142 and output the input from the channel 142 to the lane 141. The switch 143 is, for example, a crossbar switch (XBAR) or a network on chip (NoC). The lane 141 can perform data transfer with any channel 142 via the switch 143. Similarly, the channel 142 can perform data transfer with any lane 141 via the switch 143.

The memory interface 140 may determine a position at which the data input from the data transfer circuit 130 is read or written. The memory interface 140 may determine a write position for each of the pieces of data input to the lanes 141-1 to 141-N. The memory interface 140 may determine a read position for each of the channels 121 of the memory unit 120.

The memory interface 140 may determine a position at which the data input from the data transfer circuit 130 is read or written based on control information. The control information is information for controlling a write position or a read position of the data.

The control information may include position information indicating the channel 121 of the memory unit 120. The position information indicating the channel 121 may be identification information indicating the channel 121. The identification information indicating the channel 121 may be a channel number assigned to each of the channels 121. The position information indicating the channel 121 may include channel offset information. The channel offset information may be an offset value indicating a difference of the channel number.

The control information may include position information indicating an address in the channel 121. The position information indicating the address may be information indicating a reference address. Hereinafter, the reference address is also referred to as a “base address”. The position information indicating the address may be address offset information. The address offset information may be an offset value indicating a difference from the base address.

The control information may include position information indicating an address for each of the channels 121 of the memory unit 120. The control information may include information indicating a base address for each of the channels 121 of the memory unit 120. The control information may include address offset information for each of the channels 121 of the memory unit 120.

The control information may be included in a data transfer instruction. The control information may be acquired from the computing unit 110. The control information may be input to the memory interface 140 in advance and stored in a register. A portion of the control information may be included in the data transfer instruction and another portion of the control information may be stored in a register in advance. For example, identification information indicating the channel 121 or information indicating the base address may be included in the data transfer instruction and channel offset information or address offset information may be stored in a register in advance. The register for storing the control information may be included in the lane 141. The control information may be input through a path different from a path for inputting and outputting data. The acquisition source of the control information is not limited thereto, and the control information may be acquired by any method.

The lane 141 may determine, based on the control information, the channel 121 for reading and writing the data input to the lane 141. The lane 141 may determine, based on the control information, an address in the memory unit 120 for reading and writing the data input to the lane 141. The lane 141 may transmit, to the switch 143, information specifying the channel and information specifying the address. The lane 141 may transmit, to the switch 143, data to be written in the memory unit 120 together with the information specifying the channel and the information specifying the address. The information specifying the channel is an example of first information for specifying the memory to which the data is to be transmitted. The information specifying the address is an example of second information for specifying the address in the memory to which the data is to be transmitted.

For example, when the control information includes the information indicating the base address, the lane 141 may transmit, to the switch 143, a channel number previously associated with the lane 141 and the information indicating the base address. The switch 143 may transmit the information indicating the base address to the channel 142 corresponding to the channel number received from the lane 141. The channel 142 may write the data to the base address of the channel 121 or read the data from the base address of the channel 121.

For example, when the control information includes the information indicating the base address and the offset value of the channel number, the lane 141 may add the offset value to the channel number previously associated with the lane 141. The lane 141 may transmit, to the switch 143, the channel number obtained by the addition and the information indicating the base address. The switch 143 may transmit the information indicating the base address to the channel 142 corresponding to the channel number received from the lane 141. The channel 142 may write the data to the base address of the channel 121 or read the data from the base address of the channel 121.

For example, when the control information includes the information indicating the base address and the offset value of the address, the lane 141 may add the offset value to the base address. The lane 141 may transmit, to the switch 143, the channel number previously associated with the lane 141 and the information specifying the address obtained by the addition. The switch 143 may transmit the information specifying the address to the channel 142 corresponding to the channel number received from the lane 141. The channel 142 may write the data to the specified address of the channel 121 or read the data from the specified address of the channel 121.

### Specific Examples of Data Transfer Process

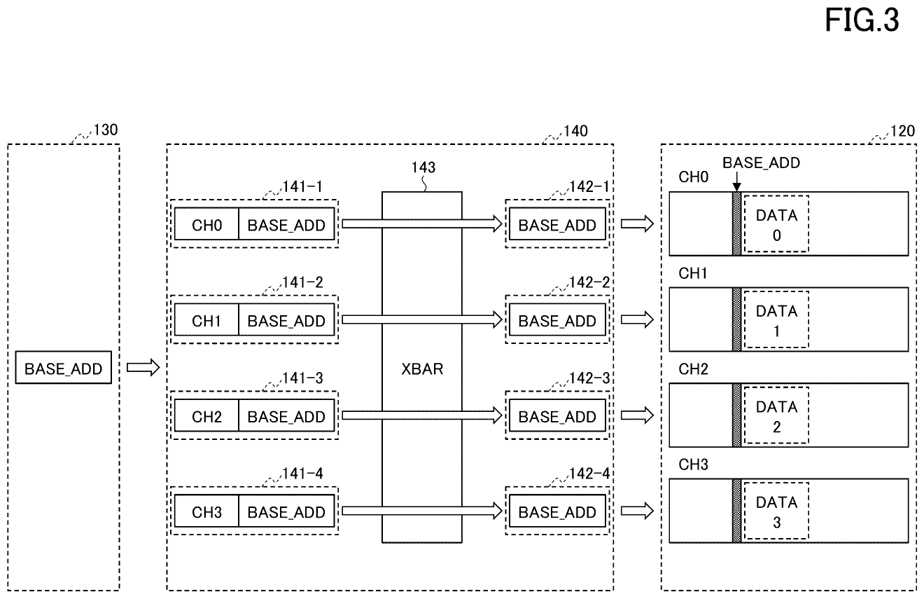

Specific examples of a data transfer process performed by the computing device 100 will be described with reference to FIGS. 3 to 6. Although FIGS. 3 to 6 illustrate specific examples of the data transfer process (the writing process) for writing data to the memory unit 120, for example, substantially the same processing may be performed in the data transfer process (the reading process) for reading data from the memory unit 120. Although FIGS. 3 to 6 illustrate data transfer from a first channel CH0 to a fourth channel CH3 among N channels of the memory unit 120, substantially the same processing may be performed in fifth and subsequent channels.

FIG. 3 is a diagram for explaining a first example of the data transfer process according to the first embodiment. FIG. 3 illustrates an example of the data transfer process when control information including information indicating a base address (BASE_ADD) is input.

The data transfer circuit 130 transfers, to the memory interface 140, the control information including the information indicating the base address. The memory interface 140 attaches a channel number predetermined for each of the lanes 141 to the information indicating the base address. FIG. 3 illustrates an example in which each of the lanes 141-1 to 141-4 attaches a channel number (CH0 to CH3) to the information indicating the base address (BASE_ADD).

Based on the channel number input from the lane 141, the switch 143 transfers the information indicating the base address to the channel 142 corresponding to the channel number. The channel 142 transfers, to the channel 121 of the memory unit 120, the information indicating the base address and the data to be written to the channel 121. The channel 121 writes the data to the base address. FIG. 3 illustrates an example in which each of the channels 121-1 to 121-4 stores, in the base address (BASE_ADD), the data (DATA0 to DATA3) input to a corresponding lane of the lanes 141-1 to 141-4.

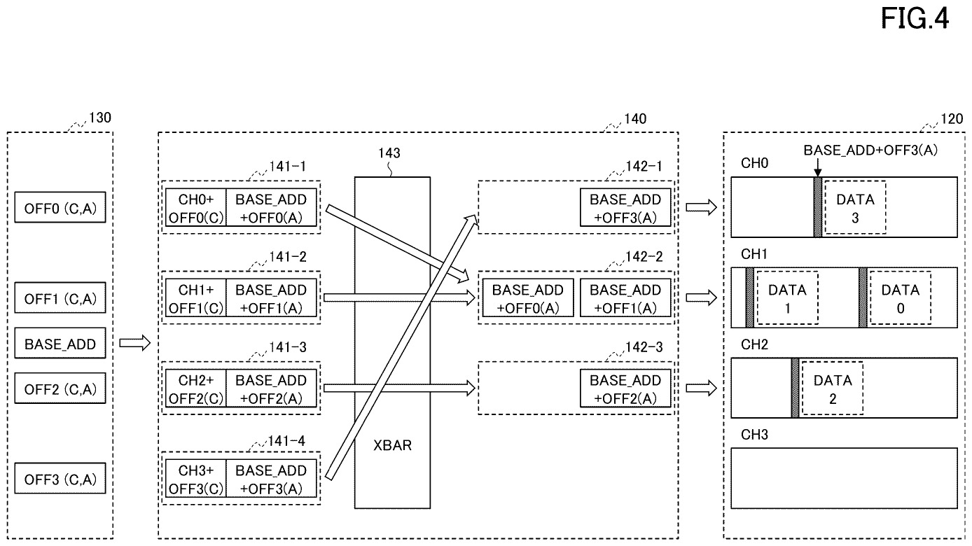

FIG. 4 is a diagram for explaining a second example of the data transfer process according to the first embodiment. FIG. 4 illustrates an example of the data transfer process when control information including information indicating a base address (BASE_ADD) and offset information (OFF0(C, A) to OFF3(C, A)) is input. Here, the offset information (OFF0(C, A) to OFF3(C, A)) includes channel offset information (OFF0(C) to OFF3(C)) and address offset information (OFF0(A) to OFF3(A)).

The data transfer circuit 130 transfers, to the memory interface 140, the control information including the information indicating the base address and the offset information. The memory interface 140 attaches a channel number predetermined for each of the lanes 141 to the information indicating the base address. FIG. 4 illustrates an example in which each of the lanes 141-1 to 141-4 attaches the channel number (CH0 to CH3) to the information indicating the base address (BASE_ADD).

Next, the memory interface 140 adds the channel offset information to the channel number for each of the lanes 141. FIG. 4 illustrates an example in which each of the lanes 141-1 to 141-4 adds the channel offset information (OFF0(C) to OFF3(C)) to the channel number (CH0 to CH3).

Additionally, the memory interface 140 adds the address offset information to the base address for each of the lanes 141. FIG. 4 illustrates an example in which each of the lanes 141-1 to 141-4 adds the address offset information (OFF0(A) to OFF3(A)) to the base address (BASE_ADD).

Based on the channel number input from the lane 141, the switch 143 transfers, to the channel 142 corresponding to the channel number, the information specifying the address. The channel 142 transfers, to the channel 121 of the memory unit 120, the information specifying the address and the data to be written to the channel 121. The channel 121 writes the data to the specified address. FIG. 4 illustrates an example in which the channel 121-1 stores the data (DATA3) input to the lane 141-4 in the address (BASE_ADD+OFF3(A)).

Here, FIG. 4 illustrates an example in which the channel 121-2 stores the data (DATA0) input to the lane 141-1 and the data (DATA1) input to the lane 141-2. In this case, the switch 143 may assign priority to two or more pieces of data stored in the same channel 121 and perform control to sequentially transfer the data to the channel 121. For example, the switch 143 may provide a FIFO (First In, First Out) buffer for input and output and perform control to sequentially transfer the data each time the communication with the channel 121 is established. In this case, the switch 143 may perform control in a fixed method or in a round-robin method.

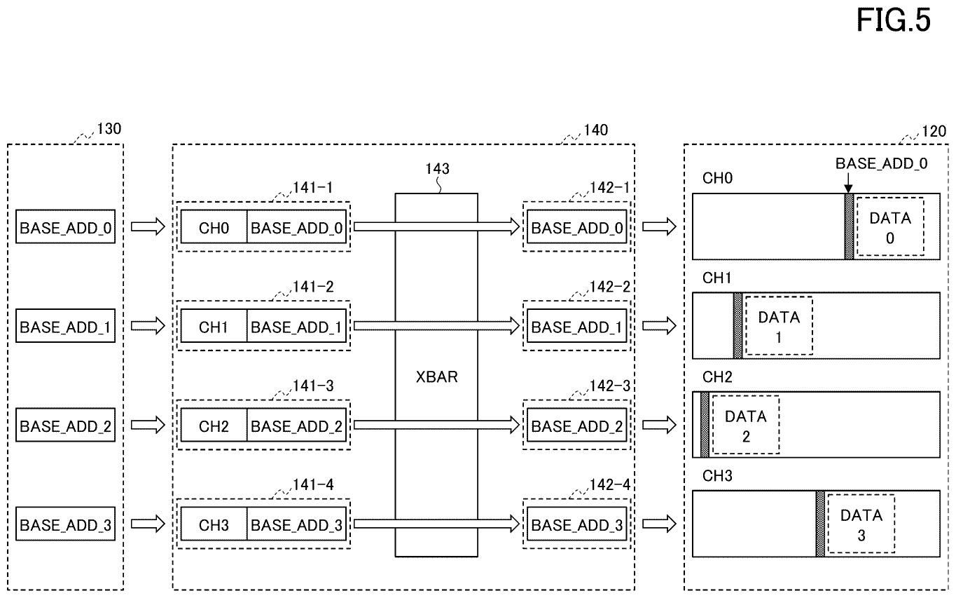

FIG. 5 is a diagram for explaining a third example of the data transfer process according to the first embodiment. FIG. 5 illustrates an example of the data transfer process when control information including information (BASE_ADD_0 to BASE_ADD_3) indicating the base address of each of the channels 121 of the memory unit 120 is input.

The data transfer circuit 130 transfers, to the memory interface 140, the control information including the information indicating the base address of each of the channels 121. The memory interface 140 attaches a channel number predetermined for each of the lanes 141 to the information indicating the base address of each of the channels 121. FIG. 5 illustrates an example in which each of lanes 141-1 to 141-4 attaches the channel number (CH0 to CH3) to the information indicating the base address (BASE_ADD_0 to BASE_ADD_3).

The switch 143 transfers the information indicating the base address to the channel 142 corresponding to the channel number based on the channel number input from the lane 141. The channel 142 transfers, to the channel 121 of the memory unit 120, the information indicating the base address and the data to be written to the channel 121. The channel 121 writes the data to the base address. FIG. 5 illustrates an example in which the channel 121-1 stores, in the base address (BASE_ADD_0), the data (DATA0) input to the lane 141-1.

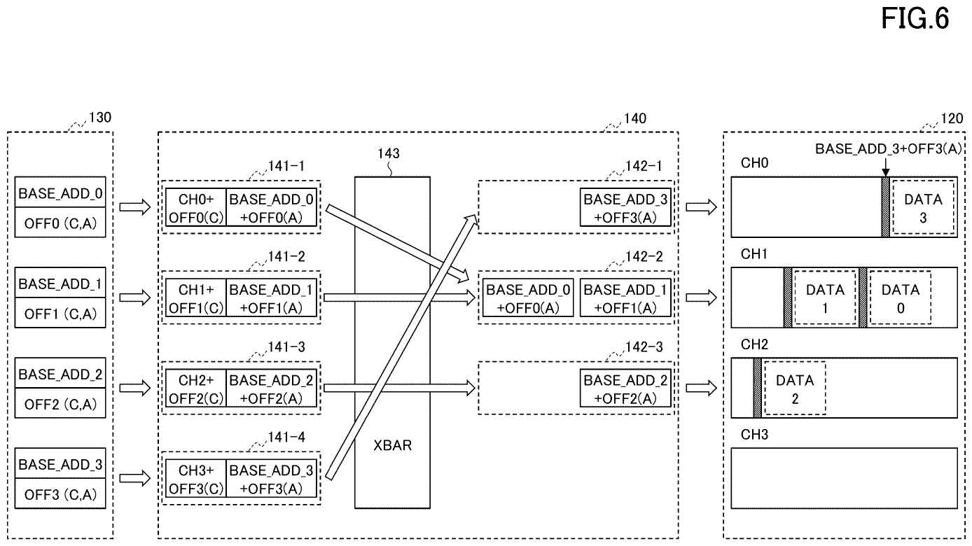

FIG. 6 is a diagram for explaining a fourth example of the data transfer process according to the first embodiment. FIG. 6 illustrates an example of the data transfer process when control information including the information indicating the base address (BASE_ADD_0 to BASE_ADD_3) and the offset information (OFF0(C, A) to OFF3(C, A)) is input to each of the channels 121 of the memory unit 120.

The data transfer circuit 130 transfers, to the memory interface 140, the control information including the information indicating the base address and the offset information for each of the channels 121. The memory interface 140 attaches a channel number predetermined for each of the lanes 141 to the information indicating the base address for each of the channels 121. FIG. 6 illustrates an example in which each of the lanes 141-1 to 141-4 attaches the channel number (CH0 to CH3) to the information indicating the base address (BASE_ADD_0 to BASE_ADD_3).

Next, the memory interface 140 adds the channel offset information to the channel number for each of the lanes 141. FIG. 6 illustrates an example in which each of the lanes 141-1 to 141-4 adds the channel offset information (OFF0(C) to OFF3(C)) to the channel number (CH0 to CH3).

Additionally, the memory interface 140 adds the address offset information to the base address of each of the channels 121 for each of the lanes 141. FIG. 6 illustrates an example in which each of the lanes 141-1 to 141-4 adds the address offset information (OFF0(A) to OFF3(A)) to the base address (BASE_ADD_0 to BASE_ADD_3).

The switch 143 transfers the information specifying the address to the channel 142 corresponding to the channel number based on the channel number input from the lane 141. The channel 142 transfers, to the channel 121 of the memory unit 120, the information specifying the address and the data to be written to the channel 121. The channel 121 writes the data to the specified address. FIG. 6 illustrates an example in which the channel 121-1 stores, in the address (BASE_ADD_3+OFF3(A)), the data (DATA3) input to the lane 141-4.

### <Flow of Data Transfer Process>

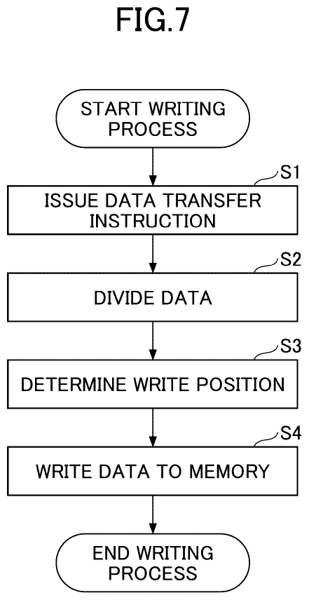

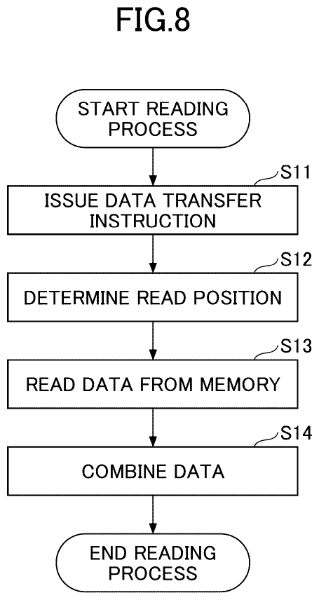

A flow of the data transfer process performed by the computing device 100 will be described with reference to FIGS. 7 and 8. The data transfer process performed by the computing device 100 may include, for example, a writing process (see FIG. 7) and a reading process (see FIG. 8).

FIG. 7 is a flowchart illustrating an example of a writing process according to the first embodiment. The writing process is a data transfer process of writing data to the memory unit 120 in response to a write instruction issued from the data transfer circuit 130.

In step S1, the data transfer circuit 130 of the computing device 100 issues the data transfer instruction (the write instruction). The data transfer instruction is input to the memory interface 140. The memory interface 140 receives the data transfer instruction. The memory interface 140 stores the control information included in the data transfer instruction in the register of the lane 141. Here, a part of the control information (e.g., the offset information) may be stored in advance in the register of the lane 141.

In step S2, the memory interface 140 of the computing device 100 acquires the data input from the data transfer circuit 130. The memory interface 140 divides the data input from the data transfer circuit 130 into N pieces. The data input from the data transfer circuit 130 includes the data transferred from the computing unit 110. In other words, the memory interface 140 collectively acquires N pieces of data from the computing unit 110. The memory interface 140 inputs the divided N pieces of data into the lanes 141-1 to 141-N, respectively.

In step S3, the lane 141 of the memory interface 140 reads the control information stored in the register of the lane 141. The lane 141 determines the write position of the data input to the lane 141 based on the control information. The lane 141 transmits, to the switch 143, the information specifying the channel, the information specifying the address, and the data to be written to the channel.

In step S4, the switch 143 of the memory interface 140 transfers, to the channel 142, the information specifying the address and the data to be written to the channel, based on the information specifying the channel received from the lane 141. The channel 142 transfers, to the channel 121, the information specifying the address and the data to be written to the channel received from the switch 143. The channel 121 writes the data received from the channel 142 to the specified address.

FIG. 8 is a flowchart illustrating an example of a reading process according to the first embodiment. The reading process is a data transfer process of reading data from the memory unit 120 in response to a read instruction issued from the data transfer circuit 130.

In step S11, the data transfer circuit 130 of the computing device 100 issues the data transfer instruction (the read instruction). The data transfer instruction is input to the memory interface 140. The memory interface 140 receives the data transfer instruction. The memory interface 140 stores the control information included in the data transfer instruction in the register of the lane 141. Here, a part of the control information (e.g., the offset information) may be stored in advance in the register of the lane 141.

In step S12, the lane 141 of the memory interface 140 reads the control information stored in the register of the lane 141. The lane 141 determines the read position of the data to be output from the lane 141 based on the control information. The lane 141 transmits, to the switch 143, the information specifying the channel and the information specifying the address.

In step S13, the switch 143 of the memory interface 140 transfers the information specifying the address to the channel 142, based on the information specifying the channel received from the lane 141. The channel 142 transfers, to the channel 121, the information specifying the address received from the switch 143. The channel 121 reads the data from the specified address. The channel 121 transmits the read data to the switch 143.

In step S14, the switch 143 transfers, to the lane 141, the data received from the channel 121. The lane 141 outputs, to the data transfer circuit 130, the data received from the switch 143. The memory interface 140 combines the N pieces of data respectively output from the lanes 141-1 to 141-N. The memory interface 140 outputs, to the data transfer circuit 130, the data obtained by the combination. In other words, the memory interface 140 collectively transmits the N pieces of data to the computing unit 110.

### Second Embodiment

A second embodiment of the present disclosure is an example of a configuration for providing redundancy when a part of the memory unit 120 becomes unavailable in the computing device 100 according to the first embodiment. When a part of the channels 121 of the memory unit 120 becomes unavailable, it is necessary to transfer data between only the available channels 121. At this time, it is desirable that the data transfer circuit 130 can perform substantially the same control as when all the channels 121 are available. Additionally, it is preferable that the delay caused in the data transfer can be reduced by the control for avoiding the unavailable channel 121.

Hereinafter, a computing device 100 according to the second embodiment will be described mainly with respect to differences from the first embodiment. Unless otherwise described, the computing device 100 according to the second embodiment may adopt a configuration substantially the same as that of the first embodiment.

### Specific Example of Data Transfer Process

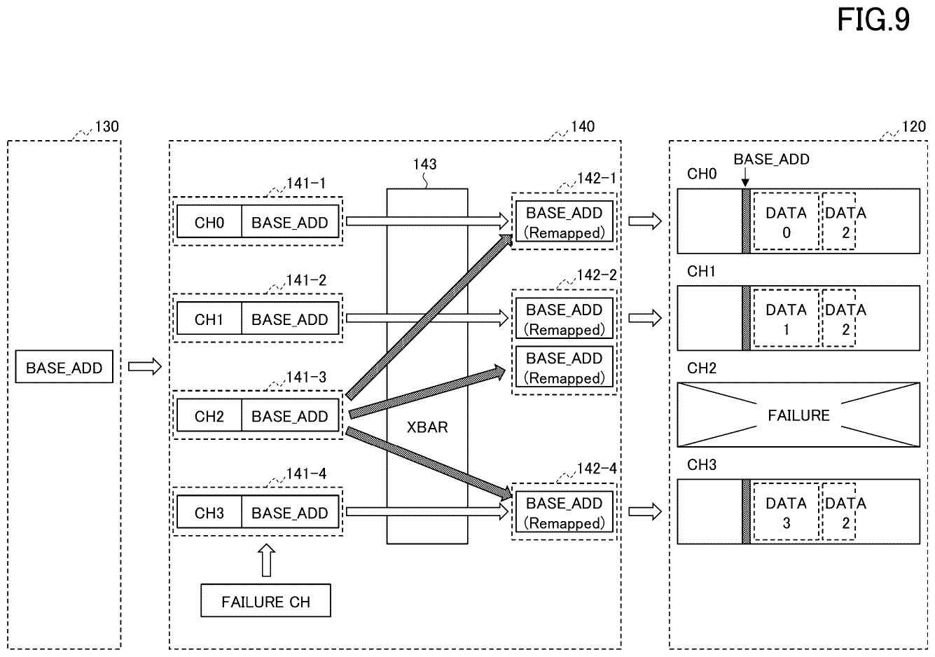

A specific example of a data transfer process performed by the computing device 100 according to the present embodiment will be described with reference to FIG. 9. Although FIG. 9 illustrates a specific example of the data transfer process (the writing process) of writing data into the memory unit 120, for example, substantially the same processing may be performed in the data transfer process (the reading process) of reading data from the memory unit 120. Additionally, although FIG. 9 illustrates data transfer for four channels CH0 to CH3 among the N channels of the memory unit 120, substantially the same processing may be performed for the fifth and subsequent channels.

FIG. 9 is a diagram for explaining an example of the data transfer process according to the second embodiment. FIG. 9 illustrates an example of the data transfer process when control information including information indicating a base address (BASE_ADD) is input.

The memory interface 140 detects a failure in the memory unit 120. The memory interface 140 may detect a failure in each of the channels 121 of the memory unit 120. For example, the memory interface 140 may determine whether each of the channels 121 is available at predetermined time intervals. Additionally, for example, the memory interface 140 may determine whether each of the channels 121 is available when the data transfer instruction is input from the data transfer circuit 130. When there is a channel 121 determined to be unavailable, the memory interface 140 may detect a failure in the channel 121.

The memory interface 140 stores availability information for the channel 121. The availability information may include information indicating a faulty (unavailable) channel 121 (failure CH). The availability information may include information indicating a non-faulty (available) channel 121. For example, the memory interface 140 may store the availability information in the register of lane 141.

A failure of the memory unit 120 may be detected by an external inspection device. The detection of the failure by the external inspection device may be performed before starting the use of the computing device 100 (e.g., at the time of manufacture or shipment by the manufacturer of the computing device 100). The information indicating the faulty channel 121 may be externally input into the computing device 100 and stored in the register of lane 141. The memory unit 120 may generate the availability information for the channel 121 based on the externally input information indicating the faulty channel 121 and store it in the register of lane 141.

The data transfer circuit 130 transfers, to the memory interface 140, the control information including the information indicating the base address. The memory interface 140 attaches a channel number predetermined for each of the lanes 141 to the information indicating the base address.

The memory interface 140 reallocates the write position of the data when the availability information for the channel 121 is stored. The memory interface 140 may reallocate the write position of the data to be written to the faulty channel 121 to the available channel 121. The memory interface 140 may reallocate the write position of the entirety of the data, including the data to be written to the available channel 121, to the available channel 121. The memory interface 140 may reallocate the write position to allow continuous access for each of the channels 121.

The memory interface 140 reallocates the read position of the data when the availability information for the channel 121 is stored. The memory interface 140 may reallocate the read position of the data to the available channel 121 when the read position of the data indicates the faulty channel 121. The memory interface 140 may reallocate the read position of the entirety of the data, including the read position indicating the available channel 121, to the available channel 121. The memory interface 140 may reallocate the read position to allow continuous access for each of the channels 121.

For example, the memory interface 140 may reallocate data to which is allocated a write position on an unavailable channel 121 to one of the available channels 121. For example, the memory interface 140 may distribute and reallocate data to which is allocated write positions on unavailable channels 121 to all of the available channels 121. For example, the memory interface 140 may distribute and reallocate the entirety of the data input from the data transfer circuit 130 to all of the available channels 121.

FIG. 9 illustrates an example in which the channel CH2 is unavailable due to a failure. In this case, the data (DATA2) allocated to the channel CH2 may be distributed and reallocated to the available three channels CH0, CH1, and CH3. In this case, the data (DATA2) allocated to the channel CH2 may be reallocated to any one of the channels CH0, CH1, and CH3, or may be distributed and reallocated to any two of the channels CH0, CH1, and CH3. Additionally, in this case, the data (DATA0, DATA1, DATA3) to be written to the available channels CH0, CH1, and CH3 may be reallocated to other channels.

### Specific Example of Reallocation Process

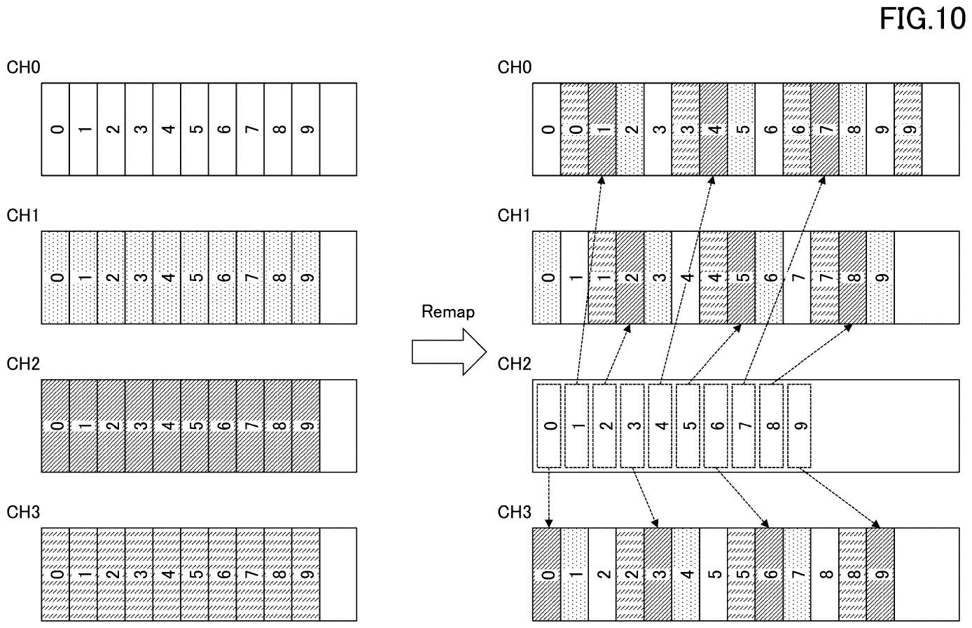

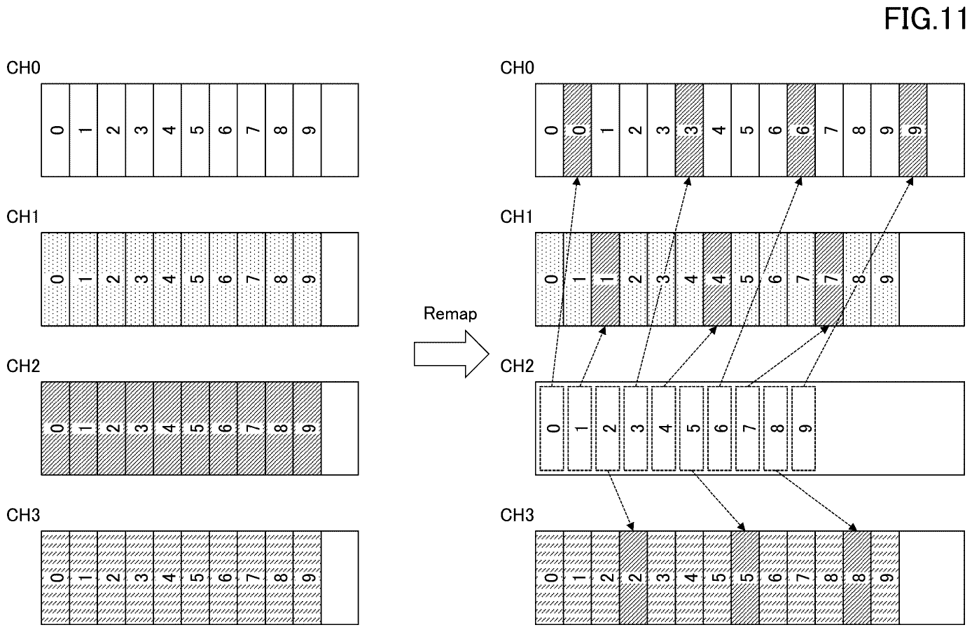

A specific example of the reallocation process performed by the computing device 100 according to the present embodiment will be described with reference to FIGS. 10 and 11. Although FIGS. 10 and 11 illustrate examples of the reallocation process to allow continuous access, the reallocation process is not limited to the examples illustrated in FIGS. 10 and 11.

FIGS. 10 and 11 illustrate a write position before reallocation (left side) and a write position after reallocation (right side). In FIGS. 10 and 11, the same shading is applied to identical data, and each rectangle represents a unit of data storage. Numbers in the rectangles are addresses. Although FIGS. 10 and 11 illustrate the reallocation process in four channels CH0 to CH3, substantially the same processing may be performed in the fifth and subsequent channels.

FIG. 10 is a diagram for explaining a first example of the reallocation process. FIG. 10 illustrates an example of write positions to be reallocated, before reallocation, by shifting the entirety of the data while avoiding an unavailable channel.

FIG. 11 is a diagram for explaining a second example of the reallocation process. FIG. 11 illustrates an example of reallocation by moving data allocated to an unavailable channel at write positions before reallocation to each of the available channels.

The reallocation process illustrated in FIG. 11 can be realized by Equations (1) and (2). Equation (1) is a mathematical expression for calculating a channel number after reallocation. Equation (2) is a mathematical expression for calculating an address after reallocation.

$$\begin{matrix}[ Eq . 1 ] & \\ RCS [ CA ] = \{ \begin{matrix}CA & if CA \neq UCA \\ DA mod N & if ( CA == UCA ) \&\& ( CA > ( DA mod N ) ) \\ ( DA mod N ) + 1 & else\end{matrix} . & ( 1 )\end{matrix}$$

$$RDA [ DA ] = \{ \begin{matrix}DA + ⌊ \frac{DA}{N} ⌋ + 1 & \begin{matrix}if ( CA == UCA ‖ ( CA < \\ ( DA mod N ) ) ‖ ( CA > UCA \&\& CA == ( DA mod N ) )\end{matrix} \\ DA + ⌊ \frac{DA}{N} ⌋ & else\end{matrix} . \qquad ( 2 )$$

Here, N is the number of channels, CA is the channel number, DA is the address of the memory, UCA is the faulty channel number, RCA is the channel number after reallocation, and RDA is the address after reallocation.

The calculation of Equations (1) and (2) can be realized by two 4-bit comparators and division of DA by N (DA/N). The division with a fixed ordinal number can be realized by combining a logically compressed decoder.

Here, the same control information is used for the write instruction and the read instruction for the same data. Therefore, the write position determined by the write instruction and the read position determined by the read instruction for the same data are pieces of information specifying the same channel and the same address. Additionally, when there is a faulty channel 121, the reallocation process of the write position and the reallocation process of the read position are performed according to the same rule. For example, when the reallocation process to allow continuous access is performed, the data writing process and the data reading process are the same as those before the reallocation process. Therefore, even when there is a faulty channel 121, the same data can be read and written by continuous access.

### <Flow of Data Transfer Process>

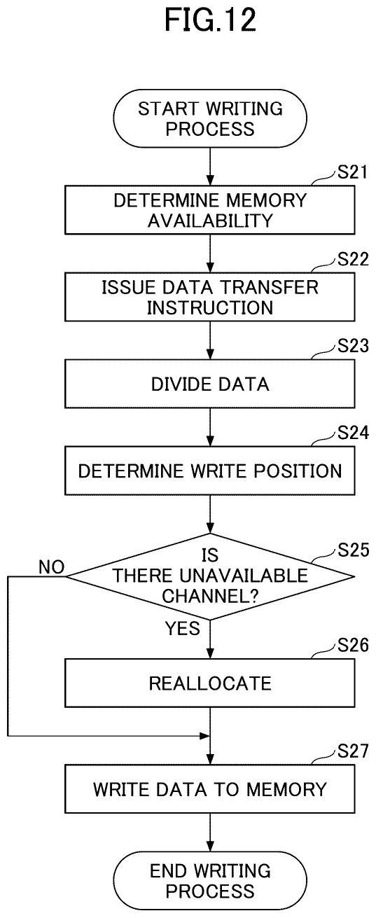

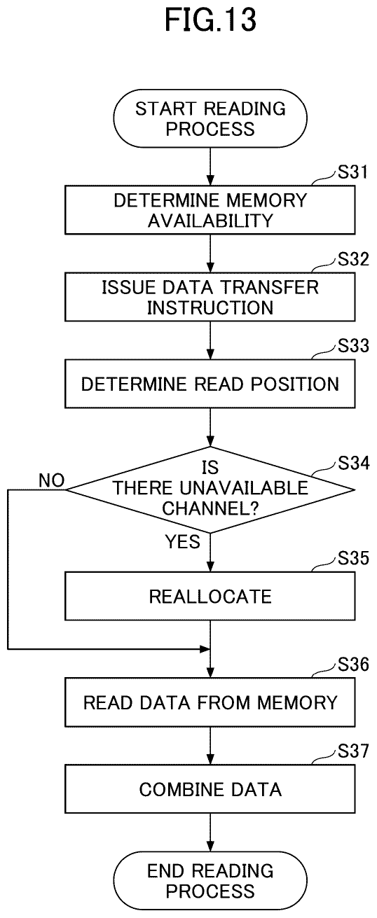

A flow of the data transfer process performed by the computing device 100 according to the present embodiment will be described with reference to FIGS. 12 and 13. FIG. 12 is a flowchart illustrating an example of the writing process according to the second embodiment.

In step S21, the memory interface 140 determines whether each of the channels 121 of the memory unit 120 is available. The memory interface 140 stores, in the register of the lane 141, the information indicating the channel 121 determined to be unavailable.

The processing from step S22 to step S24 is substantially the same as the processing from step S1 to step S3 of the writing process according to the first embodiment (see FIG. 7). That is, the memory interface 140 receives the data transfer instruction (the write instruction) from the data transfer circuit 130, and determines the write position of each data unit divided into N pieces.

In step S25, the memory interface 140 determines whether there is an unavailable channel 121 in the memory unit 120. For example, the memory interface 140 may determine whether the information indicating the faulty channel 121 is stored in the register of the lane 141.

If it is determined that there is an unavailable channel 121 (YES), the memory interface 140 proceeds to step S26. If it is determined that there is no unavailable channel 121 (in other words, all channels 121 are available) (NO), the memory interface 140 skips step S26 and proceeds to step S27.

In step S26, the memory interface 140 performs the reallocation process. The lane 141 transmits, to the switch 143, the information specifying the channel after reallocation, the information specifying the address after reallocation, and the data to be written in the channel.

In step S27, the switch 143 of the memory interface 140 transfers, to the channel 142, the information specifying the address and the data to be written in the channel based on the information specifying the channel received from the lane 141. The channel 142 transfers, to the channel 121, the information specifying the address and the data to be written in the channel received from the switch 143. The channel 121 writes the data received from the channel 142 to the specified address.

FIG. 13 is a flowchart illustrating an example of the reading process according to the second embodiment.

In step S31, the memory interface 140 determines whether each of the channels 121 of the memory unit 120 is available. The memory interface 140 stores the information indicating the channel 121 determined to be unavailable in the register of the lane 141. If the information indicating the faulty channel 121 is stored in advance, step S31 need not be performed.

The processing from step S32 to step S33 is substantially the same as the processing from step S11 to step S12 of the reading process according to the first embodiment (see FIG. 8). That is, the memory interface 140 receives the data transfer instruction (the read instruction) from the data transfer circuit 130 and determines the read position of the data.

In step S34, the memory interface 140 determines whether there is an unavailable channel 121 in the memory unit 120. If it is determined that there is an unavailable channel 121 (YES), the memory interface 140 proceeds to step S35. If it is determined that there is no unavailable channel 121 (in other words, all channels 121 are available) (NO), the memory interface 140 skips step S35 and proceeds to step S36.

In step S35, the memory interface 140 performs the reallocation process. The lane 141 transmits, to the switch 143, the information specifying the channel after reallocation and the information specifying the address after reallocation.

The processing of steps S36 and S37 is substantially the same as the processing of steps S13 and S14 of the reading process according to the first embodiment (see FIG. 8). That is, the channels 121-1 to 121-N read the data from the specified address based on the information specifying the address after reallocation. The memory interface 140 combines the data read by the channel 121-1 to 121-N and outputs, to the data transfer circuit 130, the data obtained by the combination.

### SUMMARY

As is apparent from the above description, the computing device 100 according to the embodiment of the present disclosure includes a transfer circuit and two or more memories connected to the transfer circuit. The transfer circuit acquires data from a transmission source, acquires first control information for determining a write position of the data, from the transmission source, acquires second control information for determining the write position of the data, the second control information being different from the first control information, determines the write position of the data based on the first control information and the second control information, and transmits the data to one or more memories included in the two or more memories based on the determination. The second control information includes at least information for specifying the one or more memories to which the data is to be transmitted.

The data may include at least first data and second data. The determining of the write position may include determining a write position of each of the first data and the second data based on the first control information and the second control information. The transmitting of the data may include transmitting the first data and the second data to the one or more memories included in the two or more memories based on the determination.

The computing device 100 may further include a computing circuit as the transmission source. The acquiring of the data may include the transfer circuit collectively acquiring the first data and the second data from the computing circuit.

The second control information may include offset information for each of the first data and the second data as information for specifying the one or more memories to which the data is to be transmitted. The first control information may include reference address information. The first control information need not include the information for specifying the one or more memories to which the data is to be transmitted.

The transfer circuit may divide the acquired data into the first data and the second data. The transfer circuit may divide the data into the first data and the second data based on the bandwidth of each of the two or more memories.

The transfer circuit may acquire availability information for the two or more memories. The transfer circuit may transmit the data to an available memory based on the availability information. The transfer circuit may change the write position to the available memory when the write position indicates an unavailable memory. The transfer circuit may change the write position to allow continuous access for each memory.

The computing device 100 according to the embodiment of the present disclosure includes a transfer circuit and two or more memories connected to the transfer circuit. The transfer circuit acquires first control information for determining a read position of data, from a transmission destination, acquires second control information for determining the read position of the data, the second control information being different from the first control information, determines the read position of the data based on the first control information and the second control information, receives the data from one or more memories included in the two or more memories based on the determination, and transmits the data to the transmission destination. The second control information includes at least information for specifying the one or more memories from which the data is to be received.

The determining of the read position of the data may include determining a read position of each of first data and second data based on the first control information and the second control information. The receiving of the data may include receiving the first data and the second data from the one or more memories included in the two or more memories based on the determination. The transmitting of the data may include transmitting the data including at least the first data and the second data.

The computing device 100 may further include a computing circuit as the transmission destination. The transmitting of the data may include the transfer circuit collectively transmitting the first data and the second data to the computing circuit.

The second control information may include offset information for each of the first data and the second data as the information for specifying the one or more memories from which the data is to be received. The first control information need not include the information for specifying the one or more memories from which the data is to be received.

The transfer circuit may generate the data by combining the first data and the second data based on the bandwidth of the transmission destination. The transfer circuit may acquire availability information for two or more memories. The transfer circuit may receive the data from an available memory based on the availability information. The transfer circuit may change the read position to an available memory when the read position indicates an unavailable memory. The transfer circuit may change the read position to allow continuous access for each memory. The computing circuit may execute a SIMD instruction. The data may include at least one piece of intermediate data generated using a machine learning model or parameters of the machine learning model.

Here, the transmission source or transmission destination may be the computing circuit, or an external device or circuit. Additionally, the transmission source or transmission destination may be one or more devices or circuits through which the data passes in the transmission or reception process.

The determining of the write position or the read position of the data may include generating information about the write position or the read position by computation using the first control information and the second control information. The determining of the write position or the read position of the data may be performed by another device or circuit. In this case, the other device or circuit may be included in the transfer circuit.

The first control information may be determined by internal computation by the computing circuit. The first control information may be generated or issued by the computing circuit when transmitting the data or receiving the data. The first control information may be acquired from the transmission source at the same time as the data. The first control information may be information other than information for specifying the memory to which the data is to be transmitted or from which the data is received.

The second control information may be information for directly specifying any one of the two or more memories. The second control information may be information for indirectly specifying any one of the two or more memories.

With respect to the first control information and the second control information, the acquisition source or the acquisition path may be the same or different. The first control information and the second control information may be acquired at the same timing or at different timings. Each of the first control information and the second control information may be determined by a compiler device. Each of the first control information and the second control information may be transmitted from a host device to the transfer circuit. Each of the first control information and the second control information may be generated according to an instruction sequence received from the host device. The first control information may include second control information. It may be configured such that the final write position or read position of the data is determined only by using both the first control information and the second control information.

The first control information may be information indicating the base address (BASE_ADD) illustrated in FIG. 3. The second control information may be the channel number (CH0 to CH3) illustrated in FIG. 3. In the example of FIG. 3, the first control information (BASE_ADD) does not include the second control information (CH0 to CH3).

The first control information may be the information indicating the base address (BASE_ADD) illustrated in FIG. 4. The second control information may be the channel number (CH0 to CH3) and the offset information (OFF0(C, A) to OFF3(C, A)) illustrated in FIG. 4.

The first control information may be the information indicating the base address (BASE_ADD_0 to BASE_ADD_3) illustrated in FIG. 5. The second control information may be the channel number (CH0 to CH3) illustrated in FIG. 5. In the example of FIG. 5, the first control information (BASE_ADD_0 to BASE_ADD_3) does not include the second control information (CH0 to CH3).

The first control information may be the information indicating the base address (BASE_ADD_0 to BASE_ADD_3) illustrated in FIG. 6. The second control information may be the offset information (OFF0(C, A) to OFF3(C, A)) illustrated in FIG. 6.

It is desirable to provide an effective data transfer technique to a plurality of memories, for example. Here, the effective data transfer technique to the plurality of memories may include at least one of a data transmission technique that effectively utilizes a plurality of memories and a data reception technique that effectively utilizes a plurality of memories.

Additionally, it is desirable to realize fine data handling while making the data unit handled at a time being coarse-grained. According to one embodiment of the present disclosure, because the data including the first data and the second data is transmitted to respective memories of the two or more memories, the bandwidths of the two or more memories can be collectively utilized for the data transfer. Therefore, in one aspect, according to the present disclosure, the memory can be effectively utilized. In another aspect, according to the present disclosure, fine data handling can be realized while making the data unit handled at a time being coarse-grained.

The present disclosure has the following two points, for example. The first point is that an arbitrary number and size of transfer data can be individually transferred to a memory having an arbitrary bandwidth. Here, the individual transfer indicates that transfer data is individually transmitted to an arbitrary memory or an arbitrary address in memory unit. The first point is realized by, for example, allowing the second control information to be shared as different data or at different times. The second point is that one piece of transfer data can be divided and transferred to different memories in parallel. The second point is realized, for example, by transferring data to an arbitrary memory based on the second control information.

### [Hardware Configuration of Computer]

Some or all of the computing method in the above-described embodiments may be configured by hardware or may be configured by information processing of software (program) executed by a central processing unit (CPU), a graphics processing unit (GPU), or the like. In the case where the embodiment is configured by the information processing of software, software for realizing at least some of the functions of the computing device 100 in the above-described embodiments may be stored in a non-transitory storage medium (a non-transitory computer-readable medium), such as a compact disc-read only memory (CD-ROM) or a universal serial bus (USB) memory, and a computer may read the software to perform the information processing of the software. Additionally, the software may be downloaded via a communication network. Furthermore, all or some of the processes of software may be implemented in a circuit, such as an application specific integrated circuit (ASIC) or a field programmable gate array (FPGA), and the information processing by the software may be executed by hardware.

The storage medium storing the software may be a removable medium, such as an optical disk, or a fixed storage medium, such as a hard disk or a memory. Additionally, the storage medium may be provided inside the computer (a main storage device, an auxiliary storage device, or the like) or may be provided outside the computer.

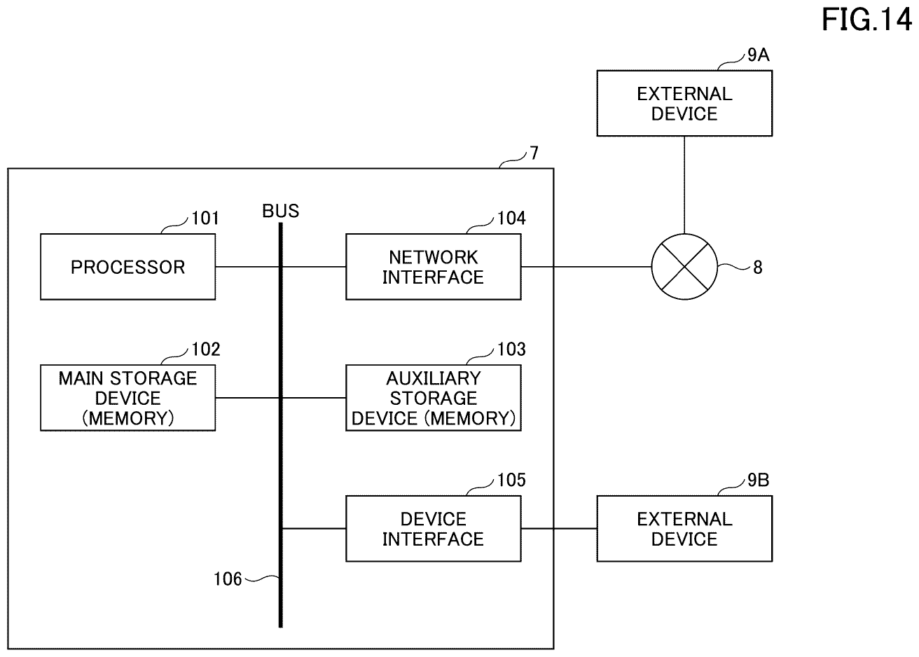

FIG. 14 is a block diagram illustrating an example of a hardware configuration of the computer including the computing device 100 in the above-described embodiments. The computer may be implemented as a computer 7 including a processor 71, a main storage device 72 (memory), an auxiliary storage device 73 (memory), a network interface 74, and a device interface 75, which are connected via a bus 76, for example. The processor 71 may include the computing device 100. The processor 71 may include another processor such as a CPU or a GPU in addition to the computing device 100.

The computer 7 of FIG. 14 includes one of each component, but may include multiple units of the same components. Additionally, although FIG. 14 illustrates one computer 7, the software may be installed in multiple computers, and the multiple computers may execute the same or different partial processes of the software. In this case, the computers may be in a distributed computing form in which the computers communicate with each other via the network interface 74 or the like to perform the processes. That is, the computer including the computing device 100 in the above-described embodiments may be configured as a system that realizes a function by one or more computers executing instructions stored in one or more storage devices. Additionally, the devices may be configured such that information transmitted from a terminal may be processed by one or more computers provided on a cloud, and the processing result may be transmitted to the terminal.

The various operations of the computer including the computing device 100 in the above-described embodiments may be performed by parallel processing using one or more processors or using multiple computers connected via a network. Additionally, various operations may be distributed to multiple operation cores in the processor and performed by parallel processing. Additionally, some or all of the processes, means, and the like of the present disclosure may be implemented by at least one of a processor or a storage device provided on a cloud that can communicate with the computer 7 via a network. As described above, the computing device 100 in the above-described embodiments may be in a form of parallel computing by one or more computers.

The processor 71 may be an electronic circuit (a processing circuit, processing circuitry, a CPU, a GPU, an FPGA, an ASIC, or the like) that performs at least one of control or operations of a computer. Additionally, the processor 71 may be any of a general-purpose processor, a dedicated processing circuit designed to execute a specific operation, or a semiconductor device including both the general-purpose processor and the dedicated processing circuit. Additionally, the processor 71 may include an optical circuit or may include an arithmetic function based on quantum computing.

The processor 71 may perform arithmetic processing based on data or software input from each device or the like of the internal configuration of the computer 7, and may output an arithmetic result or a control signal to each device or the like. The processor 71 may control each component constituting the computer 7 by executing an operating system (OS), an application, or the like of the computer 7.

The computing device 100 in the above-described embodiments may be implemented by one or more processors 71. Here, the processor 71 may refer to one or more electronic circuits disposed on one chip, or may refer to one or more electronic circuits disposed on two or more chips or two or more devices. When multiple electronic circuits are used, the electronic circuits may communicate with each other by wire or wirelessly.

The main storage device 72 may store instructions executed by the processor 71, various data, and the like, and information stored in the main storage device 72 may be read by the processor 71. The auxiliary storage device 73 is a storage device other than the main storage device 72. Here, these storage devices indicate any electronic components capable of storing electronic information, and may be semiconductor memories. The semiconductor memory may be either a volatile memory or a nonvolatile memory. The storage device for storing various data and the like in the computing device 100 in the above-described embodiments may be realized by the main storage device 72 or the auxiliary storage device 73, or may be realized by a built-in memory built in the processor 71. For example, the storage devices in the above-described embodiments may be realized by the main storage device 72 or the auxiliary storage device 73.

When the computing device 100 in the above-described embodiments includes at least one storage device (memory) and at least one processor connected (coupled) to the at least one storage device, the at least one processor may be connected to one storage device. Additionally, at least one storage device may be connected to one processor. Additionally, a configuration in which at least one processor among the multiple processors is connected to at least one storage device among the multiple storage devices may be included. Additionally, this configuration may be realized by storage devices and the processors included in multiple computers. Furthermore, a configuration in which the storage device is integrated with the processor (e.g., an L1 cache or a cache memory including an L2 cache) may be included.

The network interface 74 is an interface for connecting to a communication network 8 by wire or wirelessly. As the network interface 74, an appropriate interface, such as one conforming to an existing communication standard, may be used. The network interface 74 may exchange information with an external device 9A connected via the communication network 8. Here, the communication network 8 may be any one of a wide area network (WAN), a local area network (LAN), a personal area network (PAN), and the like, or a combination thereof, as long as information is exchanged between the computer 7 and the external device 9A. Examples of the WAN include the Internet and the like, and examples of the LAN include IEEE802.11, Ethernet (registered trademark), and the like. Examples of the PAN include Bluetooth (registered trademark), Near Field Communication (NFC), and the like.

The device interface 75 is an interface, such as a USB, that is directly connected to an external device 9B.

The external device 9A is a device connected to the computer 7 via a network. The external device 9B is a device directly connected to the computer 7.

The external device 9A or the external device 9B may be, for example, an input device. The input device is, for example, a device, such as a camera, a microphone, a motion capture device, various sensors, a keyboard, a mouse, a touch panel, or the like, and gives acquired information to the computer 7. Alternatively, the device may be a device including an input unit, a memory, and a processor, such as a personal computer, a tablet terminal, or a smartphone.

Additionally, the external device 9A or the external device 9B may be, for example, an output device. The output device may be, for example, a display device, such as a liquid crystal display (LCD) or an organic electro luminescence (EL) panel, or may be a speaker that outputs sound or the like. Alternatively, the device may be a device including an output unit, a memory, and a processor, such as a personal computer, a tablet terminal, or a smartphone.

Additionally, the external device 9A or the external device 9B may be a storage device (a memory). For example, the external device 9A may be a network storage or the like, and the external device 9B may be a storage, such as a hard disk drive (HDD).

Additionally, the external device 9A or the external device 9B may be a device having a function of a part of the components of the computing device 100 in the above-described embodiments. That is, the computer 7 may transmit a part or all of the processing result to the external device 9A or the external device 9B, or may receive a part or all of the processing result from the external device 9A or the external device 9B.

In the present specification (including the claims), if the expression “at least one of a, b, and c” or “at least one of a, b, or c” is used (including similar expressions), any one of a, b, c, a-b, a-c, b-c, or a-b-c is included. Multiple instances may also be included in any of the elements, such as a-a, a-b-b, and a-a-b-b-c-c. Further, the addition of another element other than the listed elements (i.e., a, b, and c), such as adding d as a-b-c-d, is included.

In the present specification (including the claims), if the expression such as “in response to data being input”, “using data”, “based on data”, “according to data”, or “in accordance with data” (including similar expressions) is used, unless otherwise noted, a case in which the data itself is used and a case in which data obtained by processing the data (e.g., data obtained by adding noise, normalized data, a feature amount extracted from the data, and intermediate representation of the data) is used are included. If it is described that any result can be obtained “in response to data being input”, “using data”, “based on data”, “according to data”, or “in accordance with data” (including similar expressions), unless otherwise noted, a case in which the result is obtained based on only the data is included, and a case in which the result is obtained affected by another data other than the data, factors, conditions, and/or states may be included. If it is described that “data is output” (including similar expressions), unless otherwise noted, a case in which the data itself is used as an output is included, and a case in which data obtained by processing the data in some way (e.g., data obtained by adding noise, normalized data, a feature amount extracted from the data, and intermediate representation of the data) is used as an output is included.

In the present specification (including the claims), if the terms “connected” and “coupled” are used, the terms are intended as non-limiting terms that include any of direct, indirect, electrically, communicatively, operatively, and physically connected/coupled. Such terms should be interpreted according to a context in which the terms are used, but a connected/coupled form that is not intentionally or naturally excluded should be interpreted as being included in the terms without being limited.

In the present specification (including the claims), if the expression “A configured to B” is used, a case in which a physical structure of the element A has a configuration that can perform the operation B, and a permanent or temporary setting/configuration of the element A is configured/set to actually perform the operation B may be included. For example, if the element A is a general purpose processor, the processor may have a hardware configuration that can perform the operation B and be configured to actually perform the operation B by setting a permanent or temporary program (i.e., an instruction). If the element A is a dedicated processor, a dedicated arithmetic circuit, or the like, a circuit structure of the processor may be implemented so as to actually perform the operation B irrespective of whether the control instruction and the data are actually attached.

In the present specification (including the claims), if a term indicating inclusion or possession (e.g., “comprising”, “including”, or “having”) is used, the term is intended as an open-ended term, including inclusion or possession of an object other than a target object indicated by the object of the term. If the object of the term indicating inclusion or possession is an expression that does not specify a quantity or that suggests a singular number (i.e., an expression using “a” or “an” as an article), the expression should be interpreted as being not limited to a specified number.

In the present specification (including the claims), even if an expression such as “one or more” or “at least one” is used in a certain description, and an expression that does not specify a quantity or that suggests a singular number (i.e., an expression using “a” or “an” as an article) is used in another description, it is not intended that the latter expression indicates “one”. Generally, an expression that does not specify a quantity or that suggests a singular number (i.e., an expression using “a” or “an” as an article) should be interpreted as being not necessarily limited to a particular number.

In the present specification, if it is described that a particular advantage/result is obtained in a particular configuration included in an embodiment, unless there is a particular reason, it should be understood that that the advantage/result may be obtained in another embodiment or other embodiments including the configuration. It should be understood, however, that the presence or absence of the advantage/result generally depends on various factors, conditions, and/or states, and that the advantage/result is not necessarily obtained by the configuration. The advantage/result is merely an advantage/result that is obtained by the configuration described in the embodiment when various factors, conditions, and/or states are satisfied, and is not necessarily obtained in the invention according to the claim that defines the configuration or a similar configuration.

In the present specification (including the claims), if multiple hardware performs predetermined processes, each of the hardware may cooperate to perform the predetermined processes, or some of the hardware may perform all of the predetermined processes. Additionally, some of the hardware may perform some of the predetermined processes while other hardware may perform the remainder of the predetermined processes. In the present specification (including the claims), if an expression such as “one or more hardware perform a first process and the one or more hardware perform a second process” is used, the hardware that performs the first process may be the same as or different from the hardware that performs the second process. That is, the hardware that performs the first process and the hardware that performs the second process may be included in the one or more hardware. The hardware may include an electronic circuit, a device including an electronic circuit, or the like.

In the present specification (including the claims), if multiple storage devices (memories) store data, each of the multiple storage devices (memories) may store only a portion of the data or may store an entirety of the data. Additionally, a configuration in which some of the multiple storage devices store data may be included.

In the present specification (including the claims), the terms “first”, “second”, and the like are used as a method of merely distinguishing between two or more elements and are not necessarily intended to impose technical significance on their objects, in a temporal manner, in a spatial manner, in order, in quantity, or the like. Therefore, for example, a reference to first and second elements does not necessarily indicate that only two elements can be employed there, that the first element must precede the second element, that the first element must be present in order for the second element to be present, or the like.

Although the embodiments of the present disclosure have been described in detail above, the present disclosure is not limited to the individual embodiments described above. Various additions, modifications, substitutions, partial deletions, and the like can be made without departing from the conceptual idea and spirit of the invention derived from the contents defined in the claims and the equivalents thereof. For example, in the embodiments described above, if numerical values or mathematical expressions are used for description, they are presented as an example and do not limit the scope of the present disclosure. Additionally, the order of respective operations in the embodiments is presented as an example and does not limit the scope of the present disclosure.

It should be noted that the disclosed technology may take the form of the following clauses.

### (Clause 1)

A computing device including:
a transfer circuit; and
two or more memories connected to the transfer circuit,
wherein the transfer circuit is configured to:
   acquire data from a transmission source;
   acquire first control information for determining a write position of the data, from the transmission source;
   acquire second control information for determining the write position of the data, the second control information being different from the first control information;
   determine the write position of the data based on the first control information and the second control information; and
   transmit the data to one or more memories included in the two or more memories based on the determination; and
wherein the second control information includes at least information for specifying the one or more memories to which the data is to be transmitted.

### (Clause 2)

The computing device as described in Clause 1,
wherein the data includes at least first data and second data,
wherein the determining of the write position includes determining a write position of each of the first data and the second data based on the first control information and the second control information, and
wherein the transmitting of the data includes transmitting, to the one or more memories included in the two or more memories, the first data and the second data based on the determination.

### (Clause 3)

The computing device as described in Clause 2, further including a computing circuit as the transmission source, wherein the acquiring of the data includes the transfer circuit collectively acquiring the first data and the second data from the computing circuit.

### (Clause 4)

The computing device as described in Clause 2 or 3, wherein the second control information includes offset information for each of the first data and the second data as the information for specifying the one or more memories to which the data is to be transmitted.

### (Clause 5)

The computing device as described in any one of Clauses 1 to 4, wherein the first control information includes reference address information.

### (Clause 6)

The computing device as described in any one of Clauses 1 to 5, wherein the first control information does not include the information for specifying the one or more memories to which the data is to be transmitted.

### (Clause 7)

The computing device as described in any one of Clauses 2 to 4, wherein the transfer circuit is configured to divide the acquired data into the first data and the second data.

### (Clause 8)

The computing device as described in Clause 7, wherein the transfer circuit is configured to divide the data into the first data and the second data based on bandwidths of the two or more memories.

### (Clause 9)

The computing device as described in any one of Clauses 1 to 8, wherein the transfer circuit is configured to acquire availability information for the two or more memories, and transmit the data to an available memory among the two or more memories based on the availability information.

### (Clause 10)

The computing device as described in Clause 9, wherein the transfer circuit is configured to change the write position to the available memory when the write position indicates an unavailable memory among the two or more memories.

### (Clause 11)

The computing device as described in Clause 10, wherein the transfer circuit is configured to change the write position to allow continuous access for each of the one or more memories.

### (Clause 12)

A computing device including:
a transfer circuit; and
two or more memories connected to the transfer circuit, wherein the transfer circuit is configured to:
   acquire first control information for determining a read position of data, from a transmission destination;
   acquire second control information for determining the read position of the data, the second control information being different from the first control information;
   determine the read position of the data based on the first control information and the second control information;
   receive the data from one or more memories included in the two or more memories based on the determination; and
   transmit the data to the transmission destination, and
wherein the second control information includes at least information for specifying the one or more memories from which the data is to be received.

### (Clause 13)

The computing device as described in Clause 12,
wherein the determining of the read position of the data includes determining a read position of each of first data and second data based on the first control information and the second control information,
wherein the receiving of the data includes receiving the first data and the second data from the one or more memories included in the two or more memories based on the determination, and
wherein the transmitting of the data includes transmitting the data including at least the first data and the second data.

### (Clause 14)

The computing device as described in Clause 13, further including a computing circuit as the transmission destination, wherein the transmitting the data includes the transfer circuit collectively transmitting the first data and the second data to the computing circuit.

### (Clause 15)

The computing device as described in Clause 13 or 14, wherein the second control information includes offset information for each of the first data and the second data as the information for specifying the one or more memories from which the data is to be received.

### (Clause 16)

The computing device as described in any one of Clauses 12 to 15, wherein the first control information does not include the information for specifying the one or more memories from which the data is to be received.

### (Clause 17)

The computing device as described in any one of Clauses 13 to 15, wherein the transfer circuit is configured to generate the data by combining the first data and the second data based on a bandwidth of the transmission destination.

### (Clause 18)

The computing device as described in any one of Clauses 12 to 17, wherein the transfer circuit is configured to acquire availability information for the two or more memories, and receive the data from an available memory among the two or more memories based on the availability information.

### (Clause 19)

The computing device as described in Clause 18, wherein the transfer circuit is configured to change the read position to the available memory when the read position indicates an unavailable memory among the two or more memories.

### (Clause 20)

The computing device as described in Clause 19, wherein the transfer circuit is configured to change the read position to allow continuous access for each of the one or more memories.

### (Clause 21)

The computing device as described in Clause 3 or 14, wherein the computing circuit executes a single instruction, multiple data (SIMD) instruction.

### (Clause 22)

The computing device as described in any one of Clauses 1 to 21, wherein the data includes at least one of intermediate data generated using a machine learning model or parameters of the machine learning model.

### (Clause 23)

A data transfer method performed by a computing device including a transfer circuit and two or more memories connected to the transfer circuit, the data transfer method including:
acquiring, by the transfer circuit, data from a transmission source;
acquiring, by the transfer circuit, first control information for determining a write position of the data, from the transmission source;
acquiring, by the transfer circuit, second control information for determining the write position of the data, the second control information being different from the first control information;
determining, by the transfer circuit, the write position of the data based on the first control information and the second control information; and
transmitting, by the transfer circuit, the data to one or more memories included in the two or more memories based on the determination,
wherein the second control information includes at least information for specifying the one or more memories to which the data is to be transmitted.

### (Clause 24)

A data transfer method performed by a computing unit including a transfer circuit and two or more memories connected to the transfer circuit, the data transfer method including:
acquiring, by the transfer circuit, first control information for determining a read position of the data, from a transmission destination;
acquiring, by the transfer circuit, second control information for determining the read position of the data, the second control information being different from the first control information;
determining, by the transfer circuit, the read position of the data based on the first control information and the second control information;
receiving, by the transfer circuit, the data from one or more memories included in the two or more memories based on the determination; and
transmitting, by the transfer circuit, the data to the transmission destination,
wherein the second control information includes at least information for specifying the one or more memories from which the data is to be received.

### (Clause 25)

A compiler device including one or more memories; and one or more processors, wherein the one or more processors are configured to generate instructions to be executed by the computing device as described in any one of Clauses 1 to 21.

What is claimed is:

1. A computing device comprising:
a transfer circuit; and
two or more memories connected to the transfer circuit,
wherein the transfer circuit is configured to:
acquire data from a transmission source;
acquire first control information for determining a write position of the data, from the transmission source;
acquire second control information for determining the write position of the data, the second control information being different from the first control information;
determine the write position of the data based on the first control information and the second control information; and
transmit the data to one or more memories included in the two or more memories based on the determination; and
wherein the second control information includes at least information for specifying the one or more memories to which the data is to be transmitted.

2. The computing device as claimed in claim 1,
wherein the data includes at least first data and second data,
wherein the determining of the write position includes determining a write position of each of the first data and the second data based on the first control information and the second control information, and
wherein the transmitting of the data includes transmitting, to the one or more memories included in the two or more memories, the first data and the second data based on the determination.

3. The computing device as claimed in claim 2, further comprising a computing circuit as the transmission source,
wherein the acquiring of the data includes the transfer circuit collectively acquiring the first data and the second data from the computing circuit.

4. The computing device as claimed in claim 2, wherein the second control information includes offset information for each of the first data and the second data as the information for specifying the one or more memories to which the data is to be transmitted.

5. The computing device as claimed in claim 1, wherein the first control information includes reference address information.

6. The computing device as claimed in claim 1, wherein the first control information does not include the information for specifying the one or more memories to which the data is to be transmitted.

7. The computing device as claimed in claim 2, wherein the transfer circuit is configured to divide the acquired data into the first data and the second data.

8. The computing device as claimed in claim 7, wherein the transfer circuit is configured to divide the data into the first data and the second data based on bandwidths of the two or more memories.

9. The computing device as claimed in claim 1, wherein the transfer circuit is configured to acquire availability information for the two or more memories, and transmit the data to an available memory among the two or more memories based on the availability information.

10. The computing device as claimed in claim 9, wherein the transfer circuit is configured to change the write position to the available memory when the write position indicates an unavailable memory among the two or more memories.

11. The computing device as claimed in claim 10, wherein the transfer circuit is configured to change the write position to allow continuous access for each of the one or more memories.

12. The computing device as claimed in claim 3, wherein the computing circuit executes a single instruction, multiple data (SIMD) instruction.

13. The computing device as claimed in claim 1, wherein the data includes at least one of intermediate data generated using a machine learning model or parameters of the machine learning model.

14. A computing device comprising:
a transfer circuit; and
two or more memories connected to the transfer circuit,
wherein the transfer circuit is configured to:
acquire first control information for determining a read position of data, from a transmission destination;
acquire second control information for determining the read position of the data, the second control information being different from the first control information;
determine the read position of the data based on the first control information and the second control information;
receive the data from one or more memories included in the two or more memories based on the determination; and
transmit the data to the transmission destination, and
wherein the second control information includes at least information for specifying the one or more memories from which the data is to be received.

15. The computing device as claimed in claim 14,
wherein the determining of the read position of the data includes determining a read position of each of first data and second data based on the first control information and the second control information,
wherein the receiving of the data includes receiving the first data and the second data from the one or more memories included in the two or more memories based on the determination, and
wherein the transmitting of the data includes transmitting the data including at least the first data and the second data.

16. The computing device as claimed in claim 15, further comprising a computing circuit as the transmission destination,
wherein the transmitting the data includes the transfer circuit collectively transmitting the first data and the second data to the computing circuit.

17. The computing device as claimed in claim 15, wherein the second control information includes offset information for each of the first data and the second data as the information for specifying the one or more memories from which the data is to be received.

18. The computing device as claimed in claim 15, wherein the transfer circuit is configured to generate the data by combining the first data and the second data based on a bandwidth of the transmission destination.

19. A data transfer method performed by a computing device including a transfer circuit and two or more memories connected to the transfer circuit, the data transfer method comprising:
acquiring, by the transfer circuit, data from a transmission source;
acquiring, by the transfer circuit, first control information for determining a write position of the data, from the transmission source;
acquiring, by the transfer circuit, second control information for determining the write position of the data, the second control information being different from the first control information;
determining, by the transfer circuit, the write position of the data based on the first control information and the second control information; and
transmitting, by the transfer circuit, the data to one or more memories included in the two or more memories based on the determination,
wherein the second control information includes at least information for specifying the one or more memories to which the data is to be transmitted.

20. A data transfer method performed by a computing device including a transfer circuit and two or more memories connected to the transfer circuit, the data transfer method comprising:
acquiring, by the transfer circuit, first control information for determining a read position of data, from a transmission destination;
acquiring, by the transfer circuit, second control information for determining the read position of the data, the second control information being different from the first control information;
determining, by the transfer circuit, the read position of the data based on the first control information and the second control information;
receiving, by the transfer circuit, the data from one or more memories included in the two or more memories based on the determination; and
transmitting, by the transfer circuit, the data to the transmission destination,
wherein the second control information includes at least information for specifying the one or more memories from which the data is to be received.

21. A compiler device comprising: one or more memories; and one or more processors, wherein the one or more processors are configured to generate instructions to be executed by at least one of a first computing device or a second computing device,
wherein the first computing device comprises:
a transfer circuit; and
two or more memories connected to the transfer circuit,
wherein the transfer circuit is configured to:
acquire data from a transmission source;
acquire first control information for determining a write position of the data, from the transmission source;
acquire second control information for determining the write position of the data, the second control information being different from the first control information;
determine the write position of the data based on the first control information and the second control information; and
transmit the data to one or more memories included in the two or more memories based on the determination; and
wherein the second control information includes at least information for specifying the one or more memories to which the data is to be transmitted, and
wherein the second computing device comprises:
a transfer circuit; and
two or more memories connected to the transfer circuit,
wherein the transfer circuit is configured to:
acquire first control information for determining a read position of data, from a transmission destination;
acquire second control information for determining the read position of the data, the second control information being different from the first control information;
determine the read position of the data based on the first control information and the second control information;
receive the data from one or more memories included in the two or more memories based on the determination; and
transmit the data to the transmission destination, and
wherein the second control information includes at least information for specifying the one or more memories from which the data is to be received.
